(19) United States
(12) Patent Application Publication
(10) Pub. No.: US 2024/0348253 A1
(43) Pub. Date: Oct. 17, 2024

(54) MODULAR FABRIC ARCHITECTURE IN FPGA PRODUCTS

(71) Applicants: Atul Maheshwari, Portland, OR (US); Mahesh K. Kumashikar, Bangalore (IN); MD Altaf Hossain, Portland, OR (US); Ankireddy Nalamalpu, Portland, OR (US); Krishna Bharath Kolluru, Hillsboro, OR (US); Jeffrey Christopher Chromczak, Toronto (CA)

(72) Inventors: Atul Maheshwari, Portland, OR (US); Mahesh K. Kumashikar, Bangalore (IN); MD Altaf Hossain, Portland, OR (US); Ankireddy Nalamalpu, Portland, OR (US); Krishna Bharath Kolluru, Hillsboro, OR (US); Jeffrey Christopher Chromczak, Toronto (CA)

(21) Appl. No.: 18/757,170

(22) Filed: Jun. 27, 2024

(51) Int. Cl. H03K 19/17728; G06F 30/343; H03K 19/17736; H03K 19/17758; H03K 19/17796

(52) U.S. Cl. CPC H03K 19/17728; G06F 30/343; H03K 19/17744; H03K 19/17796; H03K 19/17758

(57) ABSTRACT

Systems or methods of the present disclosure may provide an integrated circuit device that implements one region definition, which may decrease design complexity, decrease software complexity, and increase ease of use. For example, the integrated circuit device may include programmable logic that implements one region definition. The region definition may include circuitry that may implement three-dimensional (3D) input/output circuitry, 2.5D input/output circuitry, circuitry for intra-die communication, circuitry for inter-package communication, or any combination thereof. By implementing one region definition on the integrated circuit device, time spent defining each programmable logic region may be reduced or eliminated, thereby reducing design complexity software complexity associated with the integrated circuit device.

### BACKGROUND

The present disclosure relates generally to integrated circuits, such as processors and/or field-programmable gate arrays (FPGAs). More particularly, the present disclosure relates to reducing design complexity of programmable logic devices, such as high-capacity field programmable gate arrays (FPGAs).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Modern electronics, such as computers, portable devices, network routers, data centers, Internet-connected appliances, and more, tend to include at least one integrated circuit device. Integrated circuit devices may take on a variety of forms, including processors (e.g., central processing units (CPUs)), memory devices, and programmable devices (e.g., FPGA), to name only a few examples. The programmable devices, in particular, may include a programmable fabric of logic that may be programmed (e.g., configured) and reprogrammed (e.g., reconfigured) after manufacturing to provide a wide variety of functionality based on a circuit design. For example, the programmable fabric may include a first region programmed with a first region definition and a second region programmed with a second region definition. As the number of region definitions increase, design complexity and/or software complexity may increase. Indeed, as the programmable logic devices increase in complexity, the time to market for programmable logic devices may also increase.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a top-down view of a block diagram of programmable fabric of the integrated circuit device of FIG. 1 implementing a 3D modular fabric architecture, in accordance with an embodiment of the present disclosure;

FIG. 4 is a side view of a multi-die package with four integrated circuit devices of FIG. 1 that each implement the modular fabric architecture of FIG. 3, in accordance with an embodiment of the present disclosure;

FIG. 5 is a side view of a multi-die package with four integrated circuit devices of FIG. 1 that each implement the modular fabric architecture of FIG. 3, in accordance with an embodiment of the present disclosure;

FIG. 6 is a top-down view of a block diagram of programmable fabric of two integrated circuit devices of FIG. 1 implementing a 2.5D or 3D modular fabric architecture, in accordance with an embodiment of the present disclosure;

FIG. 7 is a side view of a multi-die package with four integrated circuit devices of FIG. 1 that each implement the modular fabric architecture of FIG. 5, in accordance with an embodiment of the present disclosure;

FIG. 8 is a side view of a multi-die package with four integrated circuit devices of FIG. 1 that each implement the modular fabric architecture of FIG. 5, in accordance with an embodiment of the present disclosure;

FIG. 9 is a side view of a multi-die package with two integrated circuit devices of FIG. 1 in a 3D stack, in accordance with an embodiment of the present disclosure;

FIG. 10 is a side view of a multi-die package with two integrated circuit devices of FIG. 1 in a 3D stack, in accordance with an embodiment of the present disclosure; and

FIG. 11 is a is a block diagram of a data processing system including the integrated circuit device of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present systems and techniques relate to signal transfer between two or more integrated circuit devices. For example, the integrated circuit devices may include multiple regions (e.g., multiple sectors) disposed across the integrated circuit device. Each region may include a modular collection of programmable logic, configurable memory, and/or hardened compute functions, which may all be interconnected by programmable interconnect resources for data and/or clock routing. As used herein, “a region definition” refers to an arrangement of circuitry and/or resources within the region. For example, the integrated circuit devices may implement a region definition within each region (e.g., sector) to implement a circuit design on the integrated circuit device. In other words, in at least some embodiments, multiple regions of circuitry each have the same region definition. Indeed, in some embodiments, all regions of programmable logic circuitry of the integrated circuit device may share the same region definition. This allows for a predictability and programmability that may be found throughout the programmable logic regions of the integrated circuit device.

Embodiments of the present disclosure include an integrated circuit device that implements one region definition to decrease design complexity, decrease software complexity, and increase ease of use. For example, the integrated circuit device may be within a multi-die package that utilizes hybrid bonding interconnects (HBIs) and/or smaller pitch bumps, which may reduce overhead for signal transfer between two or more coupled dies (e.g., integrated circuit devices). Since overhead decreases, the integrated circuit device may be designed such that the regions of programmable logic circuitry of the integrated circuit device all implement one region definition. For example, the integrated circuit device may implement the same region definition across the integrated circuit device. By way of example, the programmable logic circuitry may implement circuitry for die-to-die communication. To facilitate die-to-die communication, the programmable logic circuitry may implement three-dimensional (3D) input/output circuitry for communication between two stacked integrated circuit devices, 2.5-dimensional (2.5D) input/output circuitry for communication between two integrated circuit devices mounted laterally with respect to each other, or both. The software complexity associated with the design for the integrated circuit device may also decrease as the number of region definitions increase.

By implementing a single region definition across the integrated circuit device, design complexity maybe reduced, thereby reducing an amount of time spent designing and/or manufacturing the integrated circuit device. As such, implementing one region definition in the programmable logic sectors of the integrated circuit device may decrease design complexity, decrease software complexity, and increase ease of use. Accordingly, design of the integrated circuit device may be simplified, thereby reducing design complexity and/or software complexity.

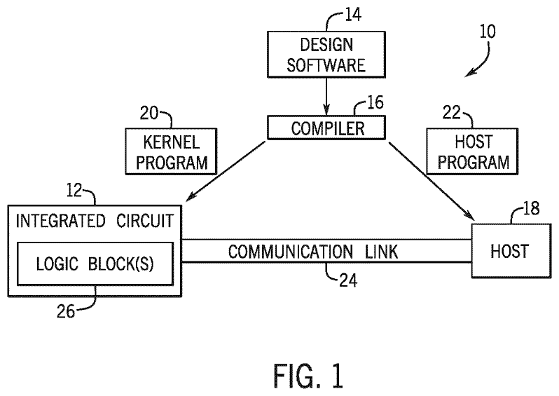

With the foregoing in mind, FIG. 1 illustrates a block diagram of a system 10 that may implement one or more functionalities. For example, a designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OpenCL™ program or SYCL™, which may enable the designer to more efficiently and easily provide programming instructions to configure a set of programmable logic cells for the integrated circuit device 12 without specific knowledge of low-level hardware description languages (e.g., Verilog or VHDL). For example, since OpenCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of a logic block 26 on the integrated circuit device 12. The logic block 26 may include circuitry and/or other logic elements and may be configured to implement arithmetic operations, such as addition and multiplication.

The designer may use the design software 14 to generate and/or to specify a low-level program, such as the low-level hardware description languages described above. For example, the design software 14 may be used to map a workload to one or more routing resources of the integrated circuit device 12 based on a timing, a wire usage, a logic utilization, and/or a routability. Additionally or alternatively, the design software 14 may be used to route first data to a portion of the integrated circuit device 12 and route second data, power, and clock signals to a second portion of the integrated circuit device 12. Further, in some embodiments, the system 10 may be implemented without a host program 22 and/or without a separate host program 22. Moreover, in some embodiments, the techniques described herein may be implemented in circuitry as a non-programmable circuit design. Thus, embodiments described herein are intended to be illustrative and not limiting.

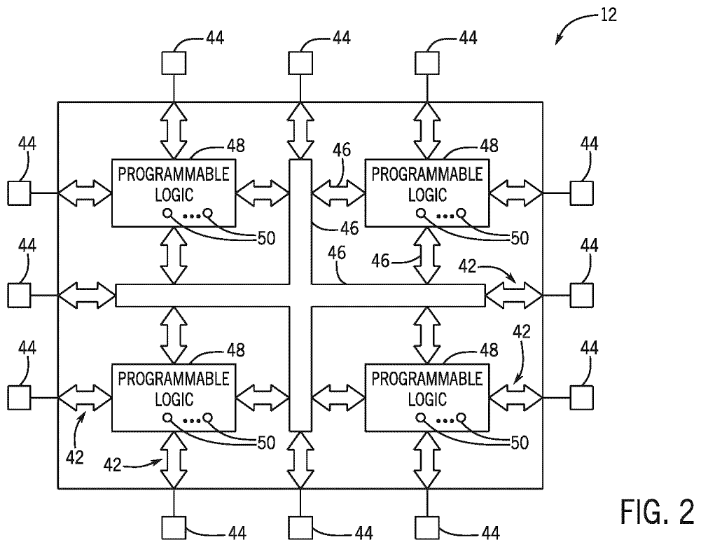

Turning now to a more detailed discussion of the integrated circuit device 12, FIG. 2 is a block diagram of an example of the integrated circuit device 12 as a programmable logic device, such as a field-programmable gate array (FPGA). Further, it should be understood that the integrated circuit device 12 may be any other suitable type of programmable logic device (e.g., a structured ASIC such as eASIC™ by Intel Corporation ASIC and/or application-specific standard product). The integrated circuit device 12 may have input/output circuitry 42 for driving signals off the device and for receiving signals from other devices via input/output pins 44. Interconnection resources 46, such as global and local vertical and horizontal conductive lines and buses, and/or configuration resources (e.g., hardwired couplings, logical couplings not implemented by designer logic), may be used to route signals on integrated circuit device 12. Additionally, interconnection resources 46 may include fixed interconnects (conductive lines) and programmable interconnects (i.e., programmable connections between respective fixed interconnects). For example, the interconnection resources 46 may be used to route signals, such as clock or data signals, through the integrated circuit device 12. Additionally or alternatively, the interconnection resources 46 may be used to route power (e.g., voltage) through the integrated circuit device 12. Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LABs). As discussed above, a designer (e.g., a user, a customer) may (re)program (e.g., (re)configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program the programmable elements 50. In general, programmable elements 50 may be based on any suitable programmable technology, such as fuses, anti-fuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. In some embodiments, the output signals may be applied to the gates of metal-oxide-semiconductor (MOS) transistors within the programmable logic 48.

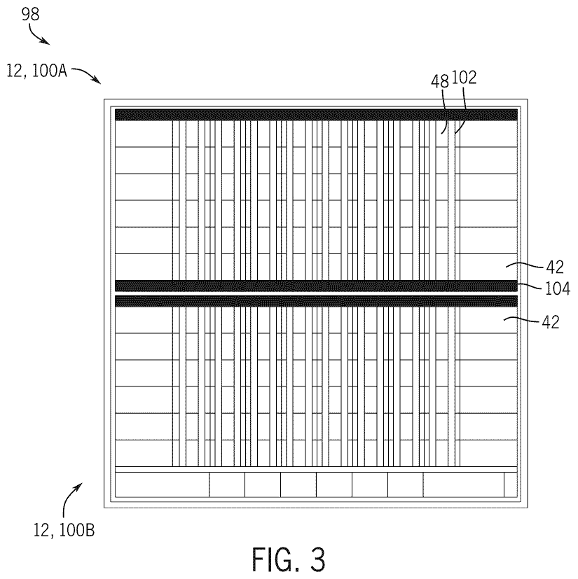

FIG. 3 is a top-down view of programmable fabric of two integrated circuit devices 12 implementing a three-dimensional (3D) modular fabric architecture. The integrated circuit devices 12 may be part of a 3D stack, such as within a multi-die package 98. The integrated circuit device 12 may implement a modular fabric architecture for 3D connectivity and/or signal transfer between the integrated circuit devices 12 in a hybrid 2.5D arrangement. As used herein, “die” and “integrated circuit device” may be used interchangeably to describe FIGS. 3-10. It may be understood that “a die” may include the integrated circuit device 12, a programmable logic device, a FPGA, or the like.

The multi-die package 98 may include a first die 100A (e.g., the integrated circuit device 12 described with respect to FIGS. 1 and 2) and a second die 100B (collectively referred to herein as a “die 100”). The die 100 may include programmable logic 48 that implements one region definition. The region definition may refer to the partitioning or segmenting of programmable logic resources into smaller regions, such as for each programmable logic region. The programmable logic resources, such as logic cells, memory blocks, input/output resources, may be allocated to different programmable logic regions of the die 100 based on the region definition. By implementing one region definition across the die 100, design complexity may decrease, software complexity may also decrease, and/or ease of use may increase.

The region definition may implement circuitry for intra-die communication, circuitry for inter-die communication, circuitry for off-package communication, and so on. For example, the region definition being implemented the programmable logic 48 of the die 100 may facilitate 3D connectivity. That is, the programmable logic 48 may implement 3D input/output circuitry 102 to facilitate die-to-die communication between two or more dies in a 3D stack. The 3D input/output circuitry 102 spread across a width of the die 100. As discussed herein, the programmable logic 48 may include at least some programmable elements 50 grouped into logic array blocks (LABs). That is, the LABs may be organized in columns across the die 100 and implement the region definition for a respective programmable logic 48. The 3D input/output circuity 102 may be spread across respective LAB columns of respective programmable logic 48. The bandwidth of the 3D input/output circuitry 102 may increase as bump pitch decreases. As such, the die 100 may be enabled with 3D connectivity.

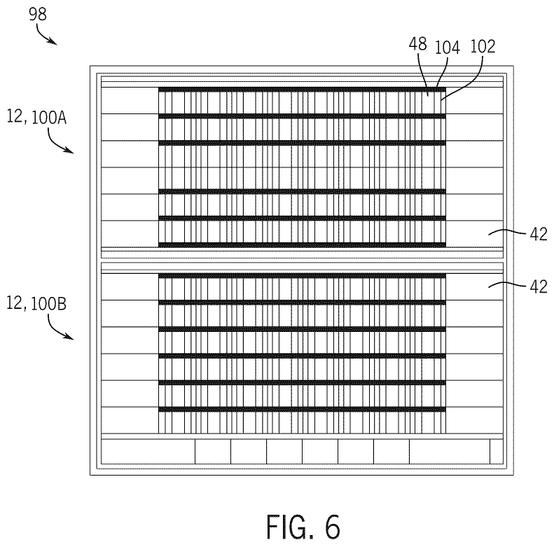

Although not illustrated, the programmable logic 48 of the die 100 may implement circuitry for intra-die communication along with the 3D input/output circuitry 102. For example, the programmable logic 48 may implement a region definition for the input/output circuitry for 3D connectivity and intra-die communication. In other embodiments, the region definition may implement 2.5-dimensional (2.5D) input/output circuitry 104 and circuitry for intra-die communication. Still in another region definition, as further described with respect to FIG. 6, the region definition may implement 3D input/output circuitry 102, 2.5D input/output circuitry 104, and circuitry for intra-die communication. That is, the die 100 may implement one region definition out of many different types of region definitions. By implementing the same region definition within the programmable logic 48 of the die 100, the design (e.g., architecture) complexity of the integrated circuit device 12 may be reduced. By reducing design complexity and/or software complexity, an amount of time used to bring the integrated circuit device 12 to market may also be reduced.

Additionally or alternatively, the programmable logic 48 may include regions that may be uniform in shape and/or size. As illustrated, the regions may be square and/or evenly distributed across the die 100. That is, the programmable logic 48 may be grouped into regions that may be uniform in shape and size throughout the die 100, which may reduce design complexity and/or software complexity. Although the illustrated programmable logic 48 of FIG. 3 appear uniform in shape and size, in certain embodiments, the die 100 may include the programmable logic 48 of different shapes and/or sizes. For example, the programmable logic 48 may be divided into rectangles, circles, ovals, and so on and cover different portions of the die 100.

The die 100 may also include 2.5D input/output circuitry 104 to facilitate die-to-die communication for two or more dies laterally (e.g., horizontally) coupled dies. The 2.5D input/output circuitry 104 may be positioned along an edge of the die 100 (e.g., a shoreline) and adjacent to the programmable logic 48. For example, one or more edge regions of the die 100 may implement the 2.5D input/output circuitry 104. As illustrated by FIG. 3, the first die 100A and the second die 100B may be laterally coupled, the 2.5D input/output circuitry 104, along with an interposer, may facilitate signal transfer between the first die 100A and the second die 100B. In certain instances, two or more laterally positioned dies may be mounted on top of an interposer and the 2.5D input/output circuitry 104 may facilitate signal transfer between each of the laterally positioned dies.

The die 100 may include input/output circuitry 42 to support off-package communication. The input/output circuitry 42 may be positioned along an edge of the die 100 and adjacent to the programmable logic 48. For example, one or more edge regions of the die 100 may implement the input/output circuitry 42. The input/output circuitry 42 may facilitate signal transfer with a device communicatively coupled to the die 100. For example, as discussed herein, the input/output circuitry 42 may drive signals off the device and receive signals from other devices, such as a memory device, via input/output pins 44. By implementing the 2.5D input/output circuitry 104 and the input/output circuitry 42 for off-package communication at the edge regions of the die 100, the programmable logic 48 of the die 100 may implement a uniform sector definition, thereby reducing design complexity of the die 100.

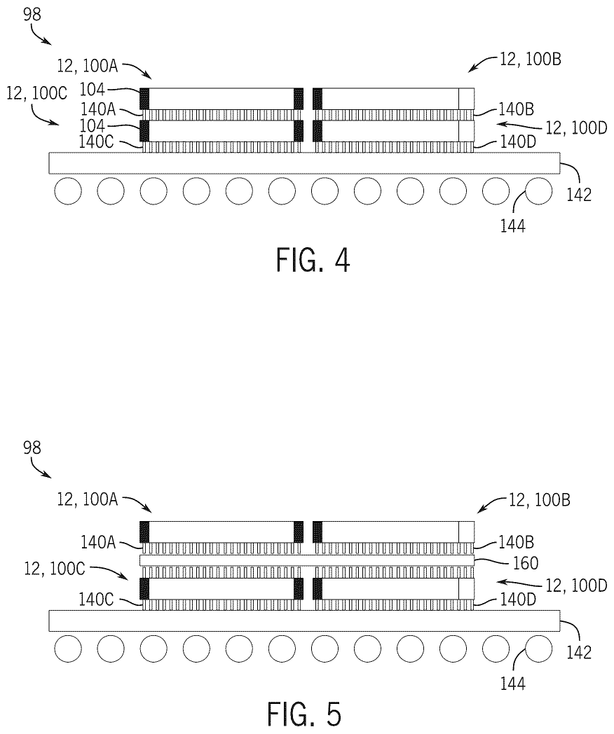

FIG. 4 is a side view of a multi-die package 98 with four integrated circuit devices 12 that each implement the modular fabric architecture of FIG. 3. In particular, the multi-die package 98 of FIG. 4 illustrates a 3D package with a first die 100A and a second die 100B stacked on top of a third die 100C and a fourth die 100D. The dies 100 each include programmable logic 48 that implement one region definition. For example, the region definition may implement the 3D input/output circuitry 102 discussed with respect to FIG. 3.

As illustrated, the integrated circuit device 12 includes the first die 100A stacked on top of the third die 100C via a first interconnect 140A and the second die 100B may be stacked on top of the fourth die 100D via a second interconnect 140B. The first interconnect 140A and the second interconnect 140B may be collectively referred to herein as the “interconnect 140.” The interconnect 140 may receive signals from the first die 100A and/or the third die 100C or signals from the second die 100B and/or the fourth die 100D and transmit the signal to the other die, respectively. For example, the first die 100A may transmit a signal to the third die 100C from the 3D input/output circuitry 102 to the interconnect 140. The third die 100C may receive the signal via the 3D input/output circuitry 102 through the interconnect 140. The interconnect 140 may include a hybrid bonding interconnect (HBI), such as a high bandwidth interconnect, one or more pitch bumps, a data path, and so on. For example, the interconnect 140 may include the HBI to couple the 3D input/output circuitry 102 of the first die 100A and the 3D input/output circuitry 102 of the third die 100C to facilitate signal transfer between the two stacked dies 100. In another example, the interconnect 140 may include bumps (e.g., pitch bumps, microbumps) between the first die 100A and the third die 100C and/or the second die 100B and the fourth die 100D. In another example, the interconnect 140 may include bumps with a fine pitch size. The bumps may be incorporated in any suitable position (e.g., middle, edge, diagonal) between the two dies to facilitate the 3D connectivity between the dies 100. In the same manner, the bumps may be incorporated in any suitable pattern or amorphous shape to facilitate the 3D connectivity. As discussed herein, the HBI and/or smaller pitch bumps may reduce overhead for die-to-die communication, and in particular 3D die-to-die communication, thereby facilitating the implementation of the 3D modular fabric architecture discussed herein.

The third die 100C and the fourth die 100D may be coupled to an interposer (e.g., bridge) 142 via by a third interconnect 140C and/or a fourth interconnect 140D, respectively. For example, the third interconnect 140C may receive signals from the third die 100C and transmit the signals to the interposer 142 for off-package communication Similarly, the fourth interconnect 140D may receive signals from the fourth die 100D and transmit the signals to the interposer 142. The interposer 142 may include bumps 144 that electrically couple the interposer 142 to other circuitry and/or a substrate for off-package communication. For example, the interposer 142 may include a programmable interconnect circuitry used to form routing connections between each die 100 mounted on the interposer 142. The bumps 144 may include solder balls, flip-chip bumps, controlled collapse chip connection (C4) bumps, and so on. For example, the multi-die package 98 may be mounted on a substrate along with other circuitry, such as a microprocessor, a debug microprocessor, memory devices, other multi-die packages, and so on. The interposer 142 may be coupled to the substrate via the bumps 144 that interface directly with the substrate. As such, the multi-die package 98 may communicate with memory devices on the substrate via the interposer 142 and/or the bumps 144. Additionally or alternatively, the interposer 142 may communicatively couple to a printed circuit board (PCB) for signal transfer to and from other circuitry mounted on the PCB.

Although the illustrated example of FIG. 4 includes four dies, in other embodiments, the integrated circuit device 12 may include any suitable number of dies coupled together in any suitable configuration. The dies may each include programmable logic 48 that implements one region definition to reduce design complexity, decrease software complexity, and improve ease of use. By using dies within a multi-die package that all implement the same region definition, the design complexity and/or software complexity of the multi-die package may decrease, thereby improving time to market for the multi-die package. In other embodiments, the multi-die package may include multiple dies that respectively implement one region definition. For example, the multi-die package may include a first die implementing a first region definition, a second die implementing a second region definition, a third die implementing a third region definition, and so on. The first region definition may be different from the second region definition, which may be different from the third region definition. However, implementing one region definition per die may decrease design complexity and/or software complexity of the multi-die package. In another embodiment, the first region definition may be the same as the second region definition, but the third region definition may be different from the first region definition and the second region definition. Still, implementing one sector definition per die may decrease design complexity and/or software complexity of the multi-die package, thereby decreasing the time to market for the multi-die package.

FIG. 5 is a side view of a multi-die package 98 with four integrated circuit devices 12 that each implement the modular fabric architecture of FIG. 3. The multi-die package 98 of FIG. 5 is substantially similar to the multi-die package 98 of FIG. 4 except the first die 100A and the second die 100B are coupled to the third die 100C and the fourth die 100D via a second interposer 160. For example, each of the dies 100 may be coupled to the second interposer 160 via a respective interconnect 140. In the illustrated example of FIG. 5, in which two laterally positioned dies (e.g., first die 100A and second die 100B) are coupled together via an interposer (e.g., the second interposer 160) and stacked on top of the third die 100C and the fourth die 100D, may be referred to as 2.5D stacking or a 2.5D connectivity.

The second interposer 160 may include a bridge in a 2.5D form, a redistribution layer (RDL), an interposer, and the like. The second interposer 160 may facilitate signal transfer between the first die 100A and the second die 100B and/or between the third die 100C and the fourth die 100D. For example, the second interposer 160 may receive signals from the 2.5D input/output circuitry 104 of the first die 100A and transfer the signals to the 2.5D input/output circuitry 104 of the second die 100B. Additionally or alternatively, the second interposer 160 may receive signals from the 3D input/output circuitry 102 of the die 100 and transmit the signal to another die. As such, the multi-die package may support both 2.5D connectivity and 3D connectivity.

FIG. 6 is a top-down view of programmable fabric of two integrated circuit devices 12 implementing a 2.5D/3D modular fabric architecture. The two integrated circuit devices 12 may be part of a 2.5D stack or 3D stack, such as part of the multi-die package 98. The integrated circuit device 12 may implement a modular fabric architecture for 2.5D connectivity and/or 3D connectivity. The integrated circuit device 12 of FIG. 6 is substantially similar to the integrated circuit device 12 of FIG. 3, except the integrated circuit device 12 of FIG. 6 does not include edge regions implementing the 2.5D input/output circuitry 104. As illustrated, the die 100 of FIG. 6 include programmable logic 48 implementing both 3D input/output circuitry 102 and 2.5D input/output circuitry 104. That is, the region definition implemented by the programmable logic 48 implements both 3D input/output circuitry 102 and 2.5D input/output circuitry 104. Additionally or alternatively, the region definition may implement circuitry for intra-die communication.

As illustrated by FIG. 6, the 3D input/output circuitry 102 may be spread across LAB columns and the 2.5D input/output circuitry 104 may be spread across LAB rows. The bandwidth for the 3D input/output circuitry 102 may increase as the bump pitch size decreases and the overhead for the 2.5D input/output circuitry 104 may decrease as bump pitch size decreases. As such, the die 100 may implement one region definition, thereby decreasing design complexity, decreasing software complexity, and improving ease of use. Although the illustrated example of FIG. 6 implements 2.5D input/output circuitry 104 across the LAB columns and 3D input/output circuitry 102 across the LAB rows, in other instances, the 3D input/output circuitry 102 may be implemented across the LAB columns and 2.5D input/output circuitry 104 may be implemented across the LAB rows. Additionally alternatively, the 3D input/output circuitry 102 or the 2.5D input/output circuitry may be implemented across both the LAB rows and the LAB columns. It may be understood that the region definition may be adjusted (e.g., repurposed, re-designed) to implement different input/output circuitry.

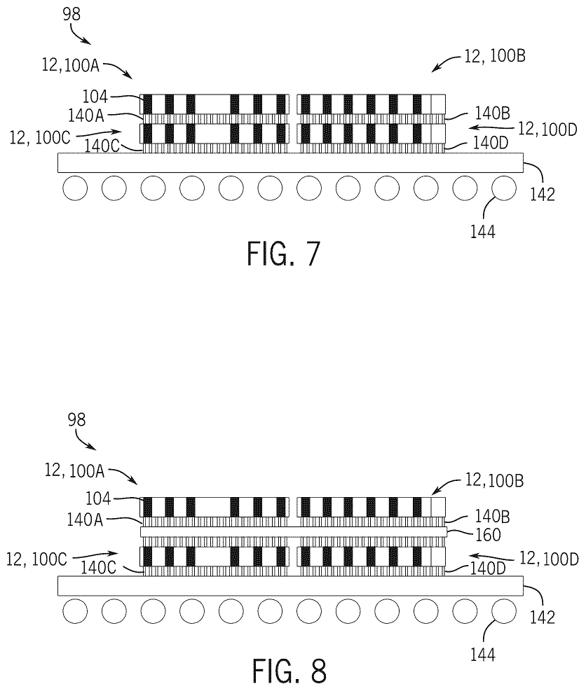

FIG. 7 is a side view of a multi-die package 98 with four integrated circuit devices 12 that each implement the modular fabric architecture of FIG. 6. That is, the dies 100 may include programmable logic 48 that implements a region definition for both 2.5D input/output circuitry 104 and 3D input/output circuitry 102.

The multi-die package 98 of FIG. 7 illustrates a 3D stack with a first die 100A and a second die 100B stacked on top of a third die 100C and a fourth die 100D. The first die 100A may be coupled to the third die 100C via a first interconnect 140A and the second die 100B and the fourth die 100D may be coupled together via a second interconnect 140B. As discussed herein, the interconnect 140 and/or the 3D input/output circuitry 102 may facilitate signal transfer between the dies 100 in the 3D stack. For example, the first die 100A may be a fabric die and the third die 100C may be a base die and the dies 100 may communicate via the 3D input/output circuitry 102 and the interconnect 140. In another example, the first die 100A may include a device manager circuit (e.g., an advanced device manager (ADM)) and the third die 100C may be memory, such as a high bandwidth memory, where the dies 100 communicate via the 3D input/output circuitry 102 and the interconnect 140. In certain instances, the overhead from the 3D connectivity may reduce HBI scaling from HBI9 to at least HBI1. As such, signal transfer between the dies 100 may improve.

The multi-die package 98 may be coupled to an interposer 142 to facilitate off-package communication. As illustrated, the third die 100C and the fourth die 100D may be coupled to the interposer 142 via a third interconnect 140C and a fourth interconnect 140D, respectively. The interposer 142 may be coupled to bumps 144 to the interposer 142 and/or the multi-die package 98 to other circuitry and/or the substrate. As such, the multi-die package 98 may communicate with other devices coupled to the substrate.

FIG. 8 is a side view of a multi-die package 98 with four integrated circuit devices 12 that each implement the modular fabric architecture of FIG. 6. In particular, the multi-die package 98 of FIG. 8 illustrates a 2.5D connectivity between the dies 100. In the 2.5D stack, the multi-die package 98 may include the second interposer 160 to facilitate signal transfer between the dies 100. As discussed herein, the second interposer 160 may include a bridge in a 2.5D form, a redistribution layer (RDL), an interposer, or the like. Additionally or alternatively, the second interposer 160 may include through-silicon vias (TSVs), or vertical vias etched or drilled through the second interposer 160, to provide vertical electrical connections between the first die 100A and the third die 100C with the second die 100B and the fourth die 100D, respectively. In another example, the second interposer 160 may include one or more metal layers patterned onto the second interposer 160 to redistribute the signals from 2.5D input/output circuitry 104 of the die 100 to one or more through-silicon vias (TSVs) and/or microbumps to facilitate the 2.5D connectivity between the dies 100.

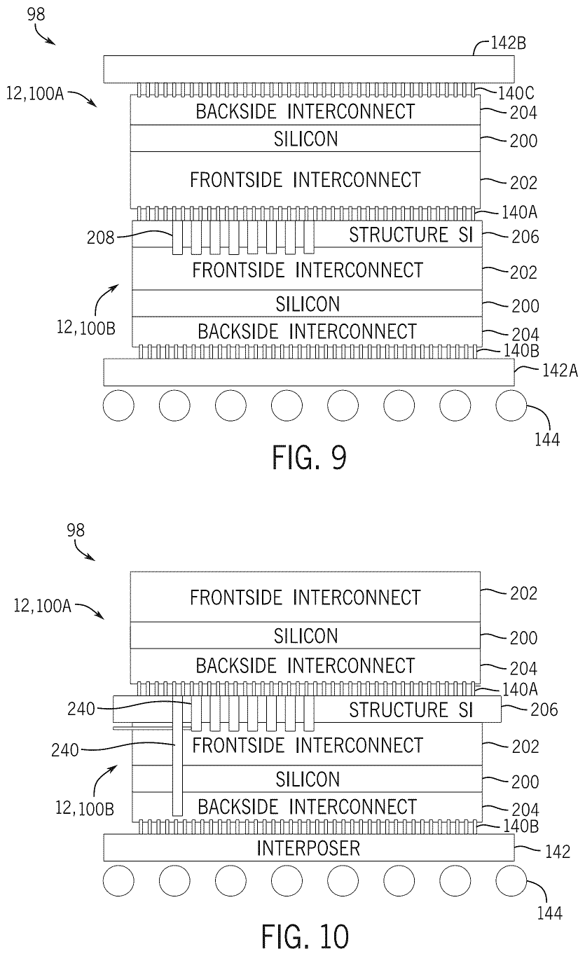

The first die 100A and/or the second die 100B may couple to the second interposer 160 via respective interconnects 140. The first die 100A may transmit to and/or receive signals from the second die 100B via the second interposer 160. Additionally or alternatively, the third die 100C and/or the fourth die 100D may couple to the second interposer 160 via respective interconnects 140. The first die 100 may transmit to and/or receive signals to the third die 100C and/or the fourth die 100D via the second interposer 160. As such, signal transfer between the dies 100 may improve. Moreover, as will be described with respect to FIGS. 9 and 10, the dies 100 may couple to the second interposer 160 via a frontside connection or a backside connection, which may improve design flexibility and decrease time to market for the multi-die package 98.

FIG. 9 is a side view of the multi-die package 98 with two integrated circuit devices 12 in a 3D stack. Each integrated circuit device 12 (e.g., die 100) may include a semiconductor substrate (e.g., silicon substrate) 200 with a first surface (e.g., frontside interconnect) 202 and a second surface (e.g., backside interconnect) 204. The semiconductor substrate 200 may include one or more components to implement the region definition for the programmable logic 48 of the dies 100. For example, the semiconductor substrate 200 may include interconnects linking logic cells, input/output pins, and/or other components of the die 100 for signals to be routed within the die and/or off-die. The first surface 202 and/or the second surface 204 may include interconnect layers formed on the surface and couple to the interconnect 140, thereby coupling to the interposer 142A, the second interposer 142B, and so on. The interconnect layers (e.g., dielectric stack) may include alternating layers of metal routing layers (e.g., dielectric layers in which metal routing paths can be formed) and via layers (e.g., dielectric layers through which metal vias can be formed for electrically connecting paths from one metal routing layer to paths in another metal routing layers). For example, the interconnect layers may include one or more connections to couple to circuitry of the interconnect 140. As such, the dies 100 may couple to circuitry for signal transfer via the first surface 202 and/or the second surface 204.

As illustrated in FIG. 9, the first die 100A and the second die 100B may be stacked in a front-to-front connection. For example, the first surface 202 of the first die 100A may couple to the first surface 202 of the second die 100B via a first interconnect 140A. To facilitate the connection, the multi-die package 98 may include a structured silicon layer 206 (e.g., the second interposer 160 described with respect to FIGS. 5 and 8) with mini through-silicon vias (miniTSVs) 208 for signal connections between the first die 100A and the second die 100B. For example, the first interconnect 140A may include the structured silicon layer 206 and/or the mini-TSVs 208. The mini-TSVs 208 may redistribute signals from the 3D input/output circuitry 102 of the first die 100A and/or the second die 100A to facilitate the 3D connectivity. As such, the 3D connectivity may be implemented in the multi-die package 98. Although the illustrated example of FIG. 9 includes mini-TSVs 208, the multi-chip package 98 may include TSVs to communicatively couple the first die 100A and the second die 100B.

Additionally or alternatively, the second die 100B may be communicatively coupled to a first interposer 142A via a second interconnect 140B and the first die 100A may be communicatively coupled to a second interposer 142B via a third interconnect 140C. As illustrated, the second surface 204 of the second die 100B may be coupled to the second interconnect 140B and the second surface 204 of the first die 100A may be coupled to the third interconnect 140C.

FIG. 10 is a side view of the multi-die package 98 with two integrated circuit devices 12 in a 3D stack. The multi-die package 98 of FIG. 10 is substantially similar to the multi-die package 98 of FIG. 9 except the first die 100A and the second die 100B are stacked in a front-to-back connection and the structured silicon layer 206 includes TSVs 240. Within the multi-die package 98 of FIG. 10, a second surface 204 of the first die 100A couples to a first surface 202 of the second die 100B via the structured silicon layer 206. As discussed herein, the surfaces of the dies 100 may include routing layers and/or via layers to facilitate electrically connecting paths from one metal routing layer to another and between dies 100. As such, the first surface 202 and/or the back surface 204 may communicatively couple the die 100 to other components within the multi-die package 98 to facilitate signal transfer between the dies 100 and/or off the multi-die package 98, such as via the interposer 142.

In certain instances, the multi-chip package 98 may implement backside power technology. For example, power may be delivered through power supply lines within the second surface 204 of the dies 100. The power supply lines may be integrated into substrate material beneath the die 100 adjacent to the second surface 204. By delivering power to the backside of a die 100, heat generated by the power dissipation may be more evenly distributed throughout the die 100, reduce electrical resistance and/or parasitic capacitance, and so on. To support the backside power technology, the structured silicon layer 206 may include TSVs 240, such as power TSVs. The TSVs 240 may extend through the structured silicon layer 206 (e.g., the second interposer 160 described with respect to FIGS. 5 and 8). The TSVs 240 may communicatively couple to a first interconnect 140A and provide power to the first die 100A through the second surface 204. The TSVs 240 may extend through the second die 100B to provide power to the second surface 204 of the second die 100B. As illustrated, the TSVs 240 may extend from the structured silicon layer 206 through the first surface 202 and the substrate 200 of the second die 100B to communicatively couple to the second surface 204 of the second die 100B. As such, the TSVs 240 may deliver power to the second surface 204 of the second die 100B and/or the second surface 204 of the first die 100A, manage thermal energy between the dies 100, and facilitate high-speed signal transfer between the dies.

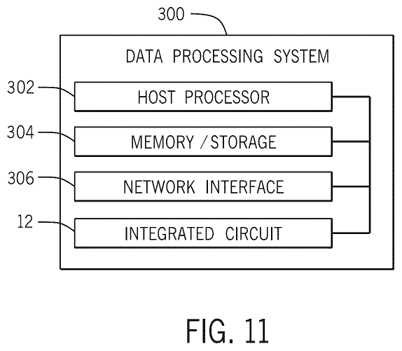

Bearing the foregoing in mind, the integrated circuit device 12 (e.g., the first die 100A, the second die 100B) may be a component included in a data processing system, such as a data processing system 300, shown in FIG. 11. The data processing system 300 may include the integrated circuit device 12 (e.g., a programmable logic device), a host processor 302 (e.g., a processor), memory and/or storage circuitry 304, and a network interface 306. The data processing system 300 may include more or fewer components (e.g., electronic display, designer interface structures, ASICs). Moreover, any of the circuit components depicted in FIG. 11 may include integrated circuits (e.g., integrated circuit device 12). The host processor 302 may include any of the foregoing processors that may manage a data processing request for the data processing system 300 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 304 may include random access memory (RAM), read-only memory (ROM), one or more hard drives, flash memory, or the like. The memory and/or storage circuitry 304 may hold data to be processed by the data processing system 300. In some cases, the memory and/or storage circuitry 304 may also store configuration programs (bit streams) for programming the integrated circuit device 12. The network interface 306 may allow the data processing system 300 to communicate with other electronic devices. The data processing system 300 may include several different packages or may be contained within a single package on a single package substrate. For example, components of the data processing system 300 may be located on several different packages at one location (e.g., a data center) or multiple locations. For instance, components of the data processing system 300 may be located in separate geographic locations or areas, such as cities, states, or countries.

In one example, the data processing system 300 may be part of a data center that processes a variety of different requests. For instance, the data processing system 300 may receive a data processing request via the network interface 306 to perform encryption, decryption, machine learning, video processing, voice recognition, image recognition, data compression, database search ranking, bioinformatics, network security pattern identification, spatial navigation, digital signal processing, or some other specialized task.

The above discussion has been provided by way of example. Indeed, the embodiments of this disclosure may be susceptible to a variety of modifications and alternative forms. Indeed, many other suitable forms of high-capacity integrated circuits can be manufactured according to the techniques outlined above. For example, the multi-chip package may include any suitable number of integrated circuits, such as 4 or more, 6 or more, 8 or more, 10 or more, and so on. The integrated circuits within the multi-chip package may each implement one region definition to reduce compilation time and/or design complexity. It may be understood that the integrated circuit devices may be programmed with a first region definition, re-programmed with a second region definition, and so on. For example, the region definition implemented on the integrated circuit devices may be adjusted to suit the designer's goals. Additionally or alternatively, the multi-chip package may include the integrated circuit devices directly stacked on each other, such a 3D stack or mounted laterally with respect to each other, such as in a 2.5D stack. Additionally or alternatively, the integrated circuit devices may be oriented in a front-to-front connection and/or a front-to-back connection.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

Example Embodiment 1. An integrated circuit package, comprising: a first die comprising a first plurality of regions of programmable logic circuitry, wherein each region of the first plurality of regions has the same first region definition, wherein the region definition comprises circuitry configurable for 2.5D communication and 3D communication; and a second die comprising a second plurality of regions of programmable logic circuitry, wherein each region of the second plurality of regions has the same second region definition.

Example Embodiment 2. The integrated circuit package of example embodiment 1, wherein the circuitry is implemented across logic array blocks (LAB) columns of the first plurality of regions and logic array columns of the first plurality of regions.

Example Embodiment 3. The integrated circuit package of example embodiment 2, wherein the circuitry implemented across the LAB columns is configurable for 3D communication and the circuitry implemented across the LAB rows is configurable for 2.5D communication.

Example Embodiment 4. The integrated circuit package of example embodiment 2, wherein the second region definition comprises circuitry for 3D communication, and wherein the first die and the second die are in a stacked configuration.

Example Embodiment 5. The integrated circuit package of example embodiment 4, comprising a third die configurable to communicatively couple to the first die via an interposer, and wherein the first die is configurable to transmit a signal to the third die via the circuitry configurable for 2.5D communication.

Example Embodiment 6. The integrated circuit package of example embodiment 1, comprising an interconnect coupling the first die and the second die in stacked configuration, and wherein the first die is configurable to transmit a signal to the second die via the circuitry.

Example Embodiment 7. The integrated circuit package of example embodiment 6, wherein interconnect comprises microbumps.

Example Embodiment 8. The integrated circuit package of example embodiment 1, wherein the second die a region of circuitry not comprising programmable logic circuitry positioned at an edge of the second die.

Example Embodiment 9. The integrated circuit package of example embodiment 7, wherein the second die is configurable for off-package communication via the region of circuitry.

Example Embodiment 10. A programmable logic device, comprising: a region of circuitry not comprising programmable logic circuitry positioned at an edge of the programmable logic device; and
a plurality of programmable logic regions configurable to implement the same region definition, wherein the region definition comprises implementing circuitry across the plurality of programmable logic regions for die-to-die communication.

Example Embodiment 11. The programmable logic device of example embodiment 10, wherein the circuitry is configurable to implement 2.5-dimensional (2.5D) input/output circuitry and three-dimensional (3D) input/output circuitry.

Example Embodiment 12. The programmable logic device of example embodiment 11, wherein the circuitry is spread across logic array block (LAB) columns and LAB rows.

Example Embodiment 13. The programmable logic device of example embodiment 11, wherein the region of circuitry is configurable to implement circuitry for off-package communication.

Example Embodiment 14. The programmable logic device of example embodiment 10, wherein the programmable logic device is configurable to communicatively couple to an additional programmable logic device in a stacked configuration and transmit a signal via the circuitry.

Example Embodiment 15. The programmable logic device of example embodiment 14, wherein a first side of the programmable logic device is configurable to couple to a first side of the additional programmable logic device by an interconnect.

Example Embodiment 16. An integrated circuit package, comprising: a first programmable logic device comprising a first plurality of programmable logic regions across the first programmable logic device, wherein each programmable logic region of the first plurality of programmable logic regions is configurable to implement a first region definition comprising first circuitry;
a second programmable logic device comprising a second plurality of programmable logic regions across the second programmable logic device, wherein each programmable logic region of the second plurality of programmable logic regions is configurable to implement a second region definition comprising second circuitry; and
an interconnect coupling the first programmable logic device and the second programmable logic device in a stacked configuration.

Example Embodiment 17. The integrated circuit package of example embodiment 16, wherein the first circuitry and the second circuitry are configurable to implement three-dimensional (3D) input/output circuitry and 2.5-dimensional (2.5D) input/output circuitry.

Example Embodiment 18. The integrated circuit package of example embodiment 16, comprising a third programmable logic device communicatively coupled to the second programmable logic device, wherein the second programmable logic device is configurable to transmit a signal to the third programmable logic device via the 2.5D input/output circuitry.

Example Embodiment 19. The integrated circuit package of example embodiment 18, comprising an interposer communicatively coupled to the second programmable logic device and the third programmable logic device and configurable to receive the signal from the second programmable logic device via the 2.5D input/output circuitry and transmit the signal to the third programmable logic device.

Example Embodiment 20. The integrated circuit package of example embodiment 16, wherein the interconnect comprises hybrid bonding interconnects.

What is claimed is:

1. An integrated circuit package, comprising:
a first die comprising a first plurality of regions of programmable logic circuitry, wherein each region of the first plurality of regions has the same first region definition, wherein the region definition comprises circuitry configurable for 2.5D communication and 3D communication; and
a second die comprising a second plurality of regions of programmable logic circuitry, wherein each region of the second plurality of regions has the same second region definition.

2. The integrated circuit package of claim 1, wherein the circuitry is implemented across logic array blocks (LAB) columns of the first plurality of regions and logic array columns of the first plurality of regions.

3. The integrated circuit package of claim 2, wherein the circuitry implemented across the LAB columns is configurable for 3D communication and the circuitry implemented across the LAB rows is configurable for 2.5D communication.

4. The integrated circuit package of claim 2, wherein the second region definition comprises circuitry for 3D communication, and wherein the first die and the second die are in a stacked configuration.

5. The integrated circuit package of claim 4, comprising a third die configurable to communicatively couple to the first die via an interposer, and wherein the first die is configurable to transmit a signal to the third die via the circuitry configurable for 2.5D communication.

6. The integrated circuit package of claim 1, comprising an interconnect coupling the first die and the second die in stacked configuration, and wherein the first die is configurable to transmit a signal to the second die via the circuitry.

7. The integrated circuit package of claim 6, wherein interconnect comprises microbumps.

8. The integrated circuit package of claim 1, wherein the second die a region of circuitry not comprising programmable logic circuitry positioned at an edge of the second die.

9. The integrated circuit package of claim 7, wherein the second die is configurable for off-package communication via the region of circuitry.

10. A programmable logic device, comprising:
a region of circuitry not comprising programmable logic circuitry positioned at an edge of the programmable logic device; and
a plurality of programmable logic regions configurable to implement the same region definition, wherein the region definition comprises implementing circuitry across the plurality of programmable logic regions for die-to-die communication.

11. The programmable logic device of claim 10, wherein the circuitry is configurable to implement 2.5-dimensional (2.5D) input/output circuitry and three-dimensional (3D) input/output circuitry.

12. The programmable logic device of claim 11, wherein the circuitry is spread across logic array block (LAB) columns and LAB rows.

13. The programmable logic device of claim 11, wherein the region of circuitry is configurable to implement circuitry for off-package communication.

14. The programmable logic device of claim 10, wherein the programmable logic device is configurable to communicatively couple to an additional programmable logic device in a stacked configuration and transmit a signal via the circuitry.

15. The programmable logic device of claim 14, wherein a first side of the programmable logic device is configurable to couple to a first side of the additional programmable logic device by an interconnect.

16. An integrated circuit package, comprising:
a first programmable logic device comprising a first plurality of programmable logic regions across the first programmable logic device, wherein each programmable logic region of the first plurality of programmable logic regions is configurable to implement a first region definition comprising first circuitry;
a second programmable logic device comprising a second plurality of programmable logic regions across the second programmable logic device, wherein each programmable logic region of the second plurality of programmable logic regions is configurable to implement a second region definition comprising second circuitry; and
an interconnect coupling the first programmable logic device and the second programmable logic device in a stacked configuration.

17. The integrated circuit package of claim 16, wherein the first circuitry and the second circuitry are configurable to implement three-dimensional (3D) input/output circuitry and 2.5-dimensional (2.5D) input/output circuitry.

18. The integrated circuit package of claim 16, comprising a third programmable logic device communicatively coupled to the second programmable logic device, wherein the second programmable logic device is configurable to transmit a signal to the third programmable logic device via the 2.5D input/output circuitry.

19. The integrated circuit package of claim 18, comprising an interposer communicatively coupled to the second programmable logic device and the third programmable logic device and configurable to receive the signal from the second programmable logic device via the 2.5D input/output circuitry and transmit the signal to the third programmable logic device.

20. The integrated circuit package of claim 16, wherein the interconnect comprises hybrid bonding interconnects.
